(19) United States
(12) Patent Application Publication
(10) Pub. No.: US 2017/0085243 A1
(43) Pub. Date: Mar. 23, 2017

(54) IMPEDANCE MATCHING INTERCONNECT

(71) Applicant: Intel Corporation, Santa Clara, CA (US)

(72) Inventors: BEOM-TAEK LEE, Mountain View, CA (US); DHANYA ATHREYA, Chandler, AZ (US); KEMAL AYGUN, Chandler, AZ (US); SUBAS BASTOLA, Santa Clara, CA (US)

(73) Assignee: Intel Corporation, Santa Clara, CA (US)

(21) Appl. No.: 14/860,318

(22) Filed: Sep. 21, 2015

(51) Int. Cl. H03H 7/38

(52) U.S. Cl. CPC H03H 7/38

(57) ABSTRACT

One embodiment provides an apparatus. The apparatus includes an impedance matching interconnect having a first end and a second end. The impedance matching interconnect includes an interface trace having a first width at the first end and a second width at the second end, the first width less than the second width. The impedance matching interconnect further includes a first dielectric layer adjacent the interface trace; a first reference plane adjacent the first dielectric layer; at least one via adjacent the first reference plane; and a second reference plane adjacent the at least one via, the at least one via to couple the first reference plane and the second reference plane. A first distance between the interface trace and the first reference plane is less than a second distance between the interface trace and the second reference plane.

FIELD

The present disclosure relates to impedance matching, in particular to, an impedance matching interconnect.

### BACKGROUND

In some electronic systems, including, for example, mobile telephones, tablet, laptop and/or desktop computers, servers, storage appliances, network systems, switch fabrics, etc., circuit elements may be coupled by interconnect systems that include one or more transmission line(s). The transmission lines may include one or more conductors (i.e., traces) and a reference plane separated by a dielectric material. Interconnect systems may be included in and/or may correspond to printed circuit boards (PCBs) and/or cables, e.g., ribbon cables. Transmission line conductors include, for example, printed circuit board (PCB) traces and/or ribbon cable traces. PCBs and/or ribbon cables, may be rigid, semi-rigid or flexible. Physical size constraints may limit maximum trace size (i.e., cross sectional area) and/or maximum spacing between traces where electrical contacts are relatively dense. In locations where physical size constraints are more relaxed, trace size may be increased to improve (i.e., decrease) transmission losses.

A characteristic impedance of a transmission line is related to, among other things, trace size and dielectric thickness between a signal trace and a reference plane. A differential impedance between traces is related to characteristic impedance, trace separation and dielectric thickness. In some applications, an allowable characteristic impedance and/or differential impedance may be specified. An associated dielectric thickness may then be determined based, at least in part on the trace width and allowable characteristic impedance.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 illustrates a cross-section of an interconnect system including an impedance matching interconnect consistent with various embodiments of the present disclosure;

FIG. 2 illustrates a top view of an interconnect system including an example impedance matching interconnect consistent with one embodiment of the present disclosure;

FIG. 3 illustrates a top view of an interconnect system including another example impedance matching interconnect consistent with one embodiment of the present disclosure;

FIG. 4A illustrates a top view of a system including an example impedance matching interconnect consistent with one embodiment of the present disclosure;

FIG. 4B illustrates a stack-up of a first end of the example interconnect of FIG. 4A;

FIG. 4C illustrates a stack-up of a second end of the example interconnect of FIG. 4A;

FIG. 5 is a plot of differential impedance for an example system consistent with one embodiment of the present disclosure; and

FIG. 6 is a plot of differential return loss for the example system characterized in FIG. 5.

Although the following Detailed Description will proceed with reference being made to illustrative embodiments, many alternatives, modifications, and variations thereof will be apparent to those skilled in the art.

### DETAILED DESCRIPTION

For example, an interconnect system may include a first region configured to meet physical size constraints and a second region configured to improve transmission losses in a second region. The first region and the second region may be coupled at a region boundary. The first region may include relatively narrow traces and a relatively thin dielectric to accommodate size constraints near, for example, a processor. The second region may include relatively wide traces to reduce losses where size constraints are relatively more relaxed. The second region may further include the relatively thin dielectric to facilitate coupling to the traces and reference plane of the first region. The impedances associated with the second region may differ from the impedances associated with the first region. Impedance mismatch may result in reflections at the region boundary between the first region and the second region and, thus, signal degradation.

Generally, this disclosure relates to an interconnect system configured to reduce and/or minimize impedance mismatch. An interconnect system consistent with the present disclosure may include a first region, a second region and an impedance matching interconnect configured to couple the first region and the second region. The impedance matching interconnect is configured to reduce and/or minimize impedance mismatch between the first region and the second region. The interconnect system may include one or more transmission lines. The first region includes a relatively narrow first trace, relatively thin first dielectric layer and a first reference plane and has an associated first characteristic impedance. The second region includes a relatively wide second trace, relatively thick second dielectric layer and a second reference plane. The thickness of the second dielectric layer may be selected so that a second characteristic impedance of the second region to corresponds to the first characteristic impedance of the first region.

The impedance matching interconnect includes an interface trace, the first dielectric layer, the first reference plane, the second reference plane and a via coupling the first reference plane and the second reference plane. The impedance matching interconnect has a first end and a second end. The first reference plane is configured to end at the second end or between the first end and the second end of the impedance matching interconnect. A shape of the end of the first reference plane may be configured to mitigate impedance mismatch in the impedance matching interconnect, as described herein.

The interface trace has a first width at the first end and a second width at the second end of the impedance matching interconnect. The first width is configured to correspond to a width of the relatively narrow first trace and the second width is configured to correspond to a width of the relatively wide second trace. A sum of the thickness of the first dielectric layer, a thickness of the first reference plane and a height of the via is configured to correspond to the thickness of the second dielectric layer.

Thus, tight space constraints may be accommodated by the first region, reduced transmission losses may be provided in the second region and impedance mismatch may be reduced and/or minimized by the impedance matching interconnect. A flexible interconnect system may remain generally flexible since the first region and the second region may be considered a two metal layer design, i.e., each of the first and second regions includes two conductive (e.g., metal) layers separated by a dielectric material.

Generally, characteristic impedance (Z0) of a transmission line is related to trace width (TW), one or more stack-up dimension(s) and properties of the dielectric (e.g., relative permittivity, ∈ᵣ). Stack-up dimensions include trace thickness (Tt), dielectric thickness (Dt) and reference plane thickness (Rt). Stack-up may include via height, as described herein. Dielectric thickness corresponds to a thickness of a dielectric material between a trace and the trace's corresponding reference plane. For example, a trace geometry may correspond to a microstrip (e.g., a top trace layer, an adjacent middle dielectric layer and an adjacent bottom reference plane). In another example, the trace geometry may correspond to a stripline (e.g., a dielectric layer that includes one or more traces embedded in the dielectric layer and an adjacent bottom reference plane. The reference plane is configured to provide a return path for signals transmitted along the trace. Differential impedance between two traces is nonlinearly related to the characteristic impedance Z0 of the traces and a ratio of trace separation (TS) to dielectric thickness Dt.

Characteristic impedance is related to a ratio of dielectric thickness and trace width. For example, the first region may have a first characteristic impedance Z0₁ related to a ratio of the width of the relatively narrow first trace and a thickness of the relatively thin first dielectric layer. The thickness of the relatively thin first dielectric layer corresponds to a first distance between the first trace and the first reference plane. The second region may have a second characteristic impedance Z0₂ related to a ratio of the width of the relatively wide second trace and a thickness of the relatively thick second dielectric layer. The thickness of the relatively thick second dielectric layer corresponds to a second distance between the second trace and the second reference plane. In order to reduce and/or minimize an impedance mismatch between Z0₁ and Z0₂, the second distance may be related to the width of the relatively wide second trace, the width of the relatively narrow first trace and the first distance.

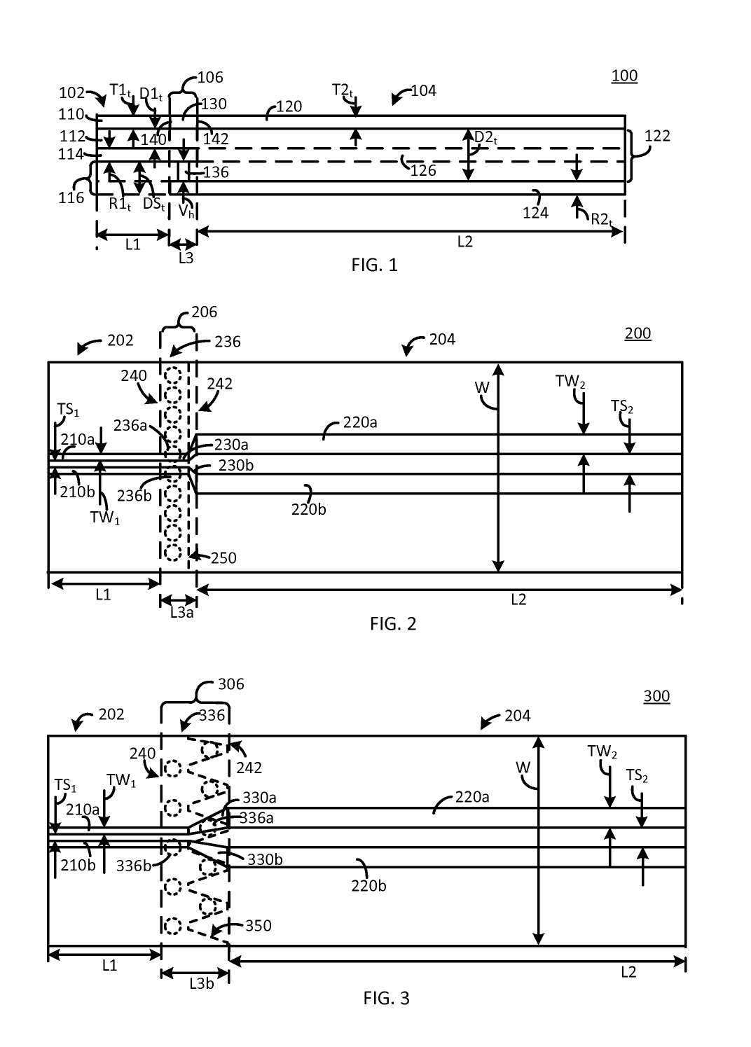

FIG. 1 illustrates a cross-section of an interconnect system 100 including an impedance matching interconnect consistent with various embodiments of the present disclosure. For example, interconnect system 100 may correspond to at least a portion of a cable (e.g., ribbon cable) that may be flexible or semi-rigid. In another example, interconnect system 100 may correspond to at least a portion of a printed circuit board (PCB). The PCB may be rigid, semi-rigid or flexible. In another example, interconnect system 100 may correspond to at least a portion of a semiconductor (i.e., integrated circuit) package substrate. The semiconductor package substrate may be rigid, semi-rigid or flexible as well. In other words, interconnect system 100 may be included in a cable, a PCB and/or an integrated circuit package substrate.

The interconnect system 100 includes a first region 102, a second region 104 and an impedance matching interconnect 106. The first region 102 may be configured for use in a location with limited space available for interconnect system 100. For example, the first region 102 may be configured for use in a breakout region at or near a processor and/or a socket configured to receive a processor. In another example, the first region 102 may be configured to couple to an integrated circuit, to a PCB and/or an electronic module with generally limited space available. The first region 102 may be flexible, partially flexible (i.e., semi-rigid) and/or rigid. The second region 104 may be configured for use in a location with relatively more relaxed space constraints. A length L2 of the second region 104 may generally be greater than a length L1 of the first region 102. A length L3 of the impedance matching interconnect 106 is less than L2 and may be less than L1. For example, the second region 104 may correspond to a mainroute region away from a processor and/or a socket configured to receive a processor. The second region 104 may be flexible, partially flexible (i.e., semi-rigid) and/or rigid.

The first region 102 includes a first trace 110, a first dielectric layer 112, a first reference plane 114 and a subplane dielectric layer 116. The first dielectric layer 112 is adjacent the first trace 110. The first reference plane 114 is adjacent the first dielectric layer 112. The subplane dielectric layer 116 is adjacent the first reference plane 114.

The first trace 110 and/or the first reference plane 114 may be constructed of a conductive material. Conductive materials may include, but are not limited to, metal, e.g., copper, Silver Palladium (AgPd), Gold Palladium (AuPd), etc. A trace width of the first trace 110 may be relatively narrow, as described herein. A trace thickness, T1ₜ, of the first trace 110 may be in the range of 10 μm to 15 μm. For example, the trace thickness may be 12 μm.

The first dielectric layer 112 may include a dielectric material. Dielectric materials may include, but are not limited to, liquid crystal polymer (LCP), glass fiber epoxy laminate (e.g., fire retardant FR4), polyimide film (e.g., Kapton®), glass microfiber reinforced PTFE (polytetrafluoroethylene) (e.g., Rogers RT/Duroid® 5870/5880 high frequency laminate) and/or combinations thereof. For example, for a flexible cable, the dielectric material may be LCP and/or polyimide film. In another example, for a PCB, the dielectric material may be FR4 (rigid) and/or Kapton® (semi-rigid or flexible).

Whether a dielectric material is flexible, semi-rigid or rigid may be further related to dielectric thickness. For example, for LCP and/or polyimide film, a dielectric thickness of 2 mil (thousandth of an inch) or less is generally flexible and a dielectric thickness of greater than about 3 mil is generally rigid.

A first distance between the first trace 110 and the first reference plane 114 corresponds to a thickness D1ₜ of the first dielectric layer 112. The first dielectric thickness D1ₜ may be relatively thin. For example, for a flexible cable, the thickness D1ₜ may be one thousandth of an inch (i.e., 0.001 inch=1 mil) with a tolerance of ±10%. In another example, for a PCB, the thickness D1ₜ may be 2.7 mil to 3.0 mil with a tolerance of ±10%.

The first reference plane 114 is configured to provide a return path for signals transmitted along one or more traces, e.g., first trace 110. For example, the first reference plane 114 may correspond to a ground plane. A thickness R1ₜ of the first reference plane is in the range of 10 μm to 15 μm. For example, for a flexible cable, R1ₜ may be 12 μm. In another example, for a PCB, R1ₜ may be 2 mils.

The subplane dielectric layer 116 includes a dielectric material, as described herein. A portion of the subplane dielectric layer 116 may correspond to a second reference plane 124, as described herein. For example, the second reference plane material may be etched away in the first region 102 during manufacturing. Removal of the conductive material is configured to enhance flexibility of a flexible or semi rigid cable or PCB. A thickness DSₜ of the subplane dielectric layer 116 may be related to a second reference plane 124 thickness R2ₜ and a via height Vₕ, as described herein.

Thus, the first region 102 may be configured for use in a location with limited space available for interconnect system 100.

The second region 104 includes a second trace 120, a second dielectric layer 122 and a second reference plane 124. The second dielectric layer 122 is adjacent the second trace 120. The second reference plane 124 is adjacent the second dielectric layer 122. The second trace 120 and/or the second reference plane 124 may be constructed of a conductive material, as described herein.

A trace width of the second trace 120 may be relatively wide, as described herein. A second trace thickness, T2ₜ, of the second trace 120 may be in the range of 10 μm to 15 μm, for example, the trace thickness may be 12 μm. In some embodiments, the trace thicknesses T1ₜ and T2ₜ may be equal.

The second dielectric layer 122 may include a dielectric material, as described herein. A second distance between the second trace 120 and the second reference plane 124 corresponds to a thickness D2ₜ of the second dielectric layer 122. The second dielectric thickness D2ₜ may be relatively thick. Thickness D2ₜ may be related to thicknesses D1ₜ and R1ₜ of the first region 102. Thickness D2ₜ may be further related to a height of via 136 of impedance matching interconnect 106, as described herein. For a flexible cable, the thickness D2ₜ may be in the range of 2 mils to 3 mils. For example, the thickness D2ₜ may be three mils with a tolerance of ±10%. For a PCB, the thickness D2ₜ may be 2 mils to 3 mils with a tolerance of ±10%. For example, the thickness D2ₜ may be 3 mils with a tolerance of ±10%. In another example, for a rigid PCB, the thickness D2ₜ may be greater than 3 mils.

The second dielectric layer 122 includes a first plane dielectric region 126. The first plane dielectric region 126 is related to first reference plane 114. First plane dielectric region 126 may be formed during manufacturing by etching the conductor associated with the first reference plane 114 in the second region 104 to create a void and providing (e.g., depositing) a dielectric material in the corresponding void. Thus, the first plane dielectric region 126 may include a dielectric material, as described herein. A thickness of the first plane dielectric region 126, included in the second dielectric layer 122 thickness D2ₜ may correspond to the thickness R1t of the first reference plane 114.

The second reference plane 124 is configured to provide a return path for signals transmitted along one or more traces, e.g., second trace 120, included in the second region 104. For example, the second reference plane 124 may correspond to a ground plane. A thickness R2ₜ of the second reference plane is in the range of 10 μm to 15 μm with a tolerance of 20% for a flexible cable. For example, for a flexible cable, R2ₜ may be 12 μm. In another example, for a PCB, R2ₜ may be 2 mils.

The impedance matching interconnect 106 includes an interface trace 130, the first dielectric layer 112, the first reference plane 114, a via 136 and the second reference plane 124. The first dielectric layer 112 is adjacent the interface trace 130. The first reference plane 114 is adjacent the first dielectric layer 112. The via 136 is adjacent the first reference plane 114. The second reference plane 124 is adjacent the via 136. A first distance between the interface trace 130 and the first reference plane 114 corresponds to D1ₜ, the first thickness of the first dielectric layer 112. A second distance between the interface trace 130 and the second reference plane 124 corresponds to D2ₜ, the second thickness of the second dielectric layer 122.

Via 136 is configured to couple, i.e., connect, the first reference plane 114 and the second reference plane 124. A height, Vₕ, of via 136 corresponds to a distance between the first reference plane 114 and the second reference plane 124. For example, Vₕ may be two mil for a flexible cable. In another example, Vₕ may be four mil for a PCB. It should be noted that height (e.g., via height) and thickness (e.g., trace thickness, dielectric thickness) correspond to a same dimension, as used herein.

For example, via 136 may correspond to a “blind” via that extends between a first outer layer of a PCB or cable to a layer within the PCB or cable but not all the way through the PCB or cable to a second outer layer. In another example, via 136 may correspond to a “buried” via that extends between two inner layers of a PCB or cable. For example, via 136 may be formed during manufacturing by creating a through hole between the second reference plane 124 and the first reference plane 114 and then introducing a conductive material into the through hole.

The impedance matching interconnect 106 has a first end 140 and a second end 142. The first end 140 corresponds to an interface (e.g., boundary) between the impedance matching interconnect 106 and the first region 102. The second end 142 corresponds to an interface (e.g., boundary) between the impedance matching interconnect 106 and the second region 104. An end of the second reference plane 124 may correspond to the first end 140 of the impedance matching interconnect 106. An end 150 of the first reference plane 114 may correspond to the second end 142 of the impedance matching interconnect 106 or may be positioned between the first end 140 and the second end 142. In other words, the first reference plane 114 may end at the second and 142 or between the first end 140 and the second end 142.

A trace width of the interface trace 130 may vary in the impedance matching interconnect 106 between the first end 140 and the second end 142, as described herein. The width of interface trace 130 at the first end 140 is configured to correspond to the width of the first trace 110. The width of interface trace 130 the second end 142 is further configured to correspond to the width of the second trace 120. The width of the first end 140 of the interface trace 130 is less than the width of the second end 142 of the interface trace 130.

Thus, relatively tight space constraints may be accommodated by the first region, reduced transmission losses may be provided in the second region and impedance mismatch may be reduced and/or minimized by the impedance matching interconnect associated with the interface region. The interconnect system 100 may remain generally flexible since each of the first region 102 and the second region 104 includes two conductive layers 110, 114 and 120, 124 separated by a respective dielectric material layer 112 and 122.

FIG. 2 illustrates a top view of an interconnect system 200 including an example impedance matching interconnect consistent with one embodiment of the present disclosure. FIG. 3 illustrates a top view of an interconnect system 300 including another example impedance matching interconnect consistent with one embodiment of the present disclosure. For example, interconnect systems 200 and 300 may correspond to interconnect system 100 of FIG. 1. FIGS. 2 and 3 may be best understood when viewed together

The interconnect systems 200, 300 each include a first region 202 and a second region 204. A width of the first region 202 is generally less than a width of the second region 204 and is related to, inter alia, number of traces, as described herein. Each interconnect system 200, 300 includes a respective impedance matching interconnect 206, 306. The first region 202 may be configured for use in a location with limited space available for interconnect system 200, as described herein. The first region 202 may be flexible, partially flexible (i.e., semi-rigid) and/or rigid. The second region 204 may be configured for use in locations with relatively more relaxed space constraints, as described herein. The first region 202 has a length L1, the second region 204 has a length L2 and the impedance matching interconnects 206, 306 have respective lengths L3a, L3b. A value of length L1 may be related to an amount of space available for the first region 202.

The first region 202 includes a plurality of relatively narrow traces, e.g., first region traces 210a, 210b, each with trace width TW₁. For example, trace width TW₁ may be in the range of 50 micrometers (μm) to 60 μm plus or minus a tolerance. For example, trace width TW₁ of first region traces 210a, 210b may be 60 μm with a tolerance of ±20%. The second region 204 includes the plurality of corresponding relatively wide traces, e.g., second region traces 220a, 220b, each with trace width TW₂. For example, trace width TW₂ may be in the range of 100 μm to 200 μm plus or minus a tolerance. For example, trace width TW₂ of the second region traces 220a, 220b may be 118 μm with a tolerance of ±20%.

The first region traces 210a, 210b have a trace separation of TS₁. The second region traces 220a, 220b have a trace separation of TS₂. A minimum trace separation is related to manufacturing considerations. For example, a minimum trace separation TS₁ and/or TS₂ for the first region and/or the second region is 60 μm. A maximum value for TS₁ is related to space constraints associated with the first region 202. Values TS₁ and/or TS₂ may be further related to target impedance values associated with, for example, traces 210a, 210b, 220a, 220b. In other words, differential impedance is related to trace separation, as described herein. Generally, TW₁ is less than TW₂ and TS₁ is less than TS₂.

The impedance matching interconnects 206, 306 each have a first end 240 and a second end 242. The first end 240 corresponds to a first boundary between the first region 202 and the respective impedance matching interconnect 206, 306. The second end 242 corresponds to a second boundary between the second region 204 and the respective impedance matching interconnect 206, 306.

The impedance matching interconnects 206, 306 include the plurality of interface traces, e.g., interface traces 230a, 230b and interface traces 330a, 330b, respectively. The impedance matching interconnects 206, 306 further include a plurality of vias, e.g., vias 236a, 236b, collectively vias 236, and vias 336a, 336b, collectively vias 336, respectively. Each of the pluralities of vias 236, 336 corresponds to via 136 of FIG. 1. In other words, the vias 236, 336 are positioned between the first reference layer and the second reference layer, e.g., layers 114 and 124 of FIG. 1. The vias 236, 336 are dotted in the figures to indicate that they are at a different layer than, e.g., interface traces 330a, 330b. The vias 236, 336 are included in FIGS. 2 and 3 to illustrate their locations relative to interface traces 230a, 230b and 330a, 330b, respectively. The vias may have a generally circular cross-section. A diameter of vias 236a, 236b may be in the range of 50 μm to 75 μm. For example, the diameter of each via in vias 236 may be 50 μm with a tolerance of 10%. Similarly, a diameter of vias 336a, 336b may be in the range of 90 μm to 110 μm. For example, the diameter of each via in vias 336 may be 100 μm with a tolerance of 10%.

A trace width of the interface traces, e.g., interface traces 230a, 230b and 330a, 330b, may vary in the impedance matching interconnect 206, 306 between the first end 240 and the second end 242. A trace width of the interface traces 230a, 330a at the first end 240 is configured to correspond to the trace width of first region traces, e.g., the trace width of first region trace 210a. Thus, the trace width of the interface trace 230a, 330a at the first end 240 is TW₁. A trace width of the interface traces 230a, 330a at the second end 242 is further configured to correspond to the trace width of second region traces, e.g., second region trace 220a. Thus, the trace width of interface trace 230a, 330a at the second end 242 is TW₂. The width at the first end 240 of the interface traces 230a, 330a is less than the width at the second end 242 of the interface traces 230a, 330a.

In one embodiment, the width of interface trace 230a, 330a may increase uniformly between the first end 240 and the second end 242, from TW₁ to TW₂. In another embodiment, the width of interface trace 230a, 330a may correspond to the width of the first trace 210a (i.e., TW₁) for at least the portion of the length L3a, L3b of the impedance matching interconnect 206, 306. For example, the portion may be related to a diameter of via 236a, 336a. Impedance matching interconnects 206, 306 are examples of this second embodiment. In this embodiment, the width of interface trace 230a, 330a may decrease uniformly from TW₂ to TW₁ from the second end 242 to a location along length L3a, L3b between the first end 240 and the second end 242. The interface trace 230a, 330a may then continue to the first end 240 with the trace width TW₁. A rate of change of interface trace width may affect impedance mismatch between the first region 202 and the second region 204. A relatively more gradual transition between TW₁ and TW₂ may correspond to a relatively smaller impedance mismatch. For example, the rate of change of trace width for interface trace, e.g., interface trace 330a, of impedance matching interconnect 306 may mitigate this impedance mismatch.

The lengths L3a, L3b of the impedance matching interconnects 206, 306 may be affected by a distribution of vias, e.g., vias 236a, 336a, and/or by a geometry of the interface traces, e.g., interface trace 230a, 330a. For example, vias 236 are generally aligned (i.e., arranged in a line) perpendicular to length L3a. In another example, vias 336 are generally staggered. The distribution of vias 236 distribution may support a relatively small L3a. A rate of change of interface trace width may be relatively higher when L3a is relatively small. The rate of change of interface trace width may also be relatively higher when the interface trace width is TW₁ for at least a portion of L3a.

The distribution of vias, e.g., vias 236 and 336, may further affect via spacing. For example, vias 236 may be relatively closely spaced across interconnect system 200 width W. In another example, vias 336 may be relatively less closely spaced across interconnect system 300 width W. Relatively less closely spaced vias, e.g., vias 336, may facilitate manufacturing the impedance matching interconnect, e.g., impedance matching interconnect 306, as well as the interconnect system 300. Further, via design rules (i.e., diameter, density, clearance, etc.) may vary depending on manufacturing capability.

In the first example 200, dotted line 250 of impedance matching interconnect 206 corresponds to an end of a first reference plane, e.g., first reference plane 114 of FIG. 1. Similarly, in the second example 300, dotted line 350 of impedance matching interconnect 306 corresponds to an end of a first reference plane, e.g., first reference plane 114 of FIG. 1. The end 250, 350 of the first reference plane corresponds to a boundary between the first dielectric thickness, i.e., dielectric thickness D1ₜ, and the second dielectric thickness D2ₜ. In the first example 200, a shape of the end 250 of the first reference plane is uniform (e.g., is a straight line) and perpendicular to the length dimension (i.e., L1, L2, L3a). The end 250 of the first reference plane may thus correspond to or be a fixed distance from the second end 242 of the impedance matching interconnect 206. In the second example 300, a shape of the end 350 of the first reference plane is nonuniform (e.g., may be a zigzag pattern). The end 350 of the first reference plane may thus be a variable distance from the second end 242 of the impedance matching interconnect 306. The nonuniform end 350 of the first reference plane is configured to mitigate impedance mismatch (e.g., reduce impedance discontinuity) in impedance matching interconnect 306 related to the boundary between the first dielectric thickness and the second dielectric thickness. A relatively smaller impedance discontinuity related to the end 350 of the first reference plane may correspond to a relatively smaller impedance mismatch between the first region 202 and the second region 204.

Thus, impedance matching interconnects 206, 306 may be configured to couple the first region 202 and the second region 204. The impedance matching interconnects 206, 306 are further configured to reduce and/or minimize impedance mismatch between the first region 202 and the second region 204. Thus, the relatively narrow trace widths and relatively narrow trace spacing of the first region 202 and the relatively wide trace widths of the second region 204 may be accommodated. Distribution of vias 236, 336 may affect lengths L3a, L3b of the impedance matching interconnect as well as spacing between adjacent vias. Increased space between vias, e.g., impedance matching interconnect 306, may correspond to a relatively more flexible interface region compared to impedance matching interconnect 206. Distribution of vias 236, 336 may be further related to a shape of the end 250, 350 of the first reference plane.

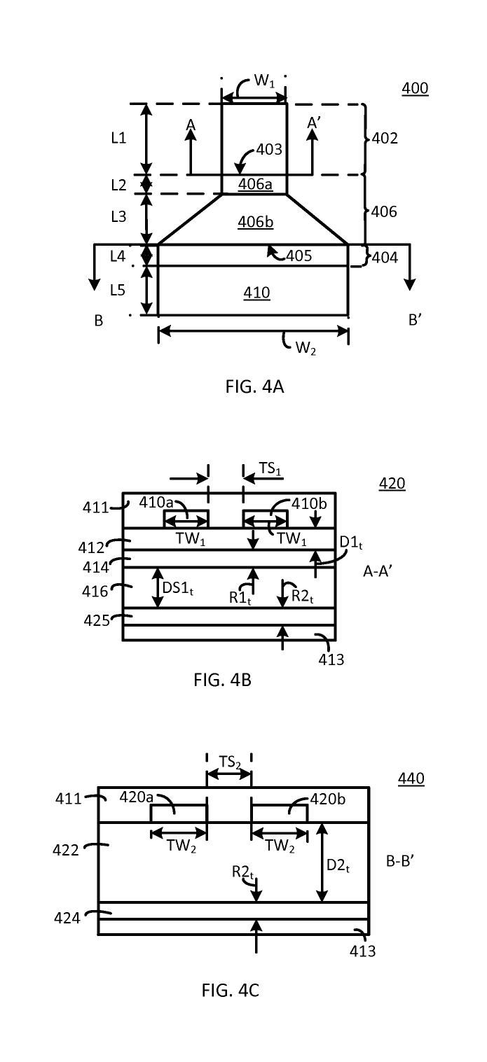

FIG. 4A illustrates a top view of an example system 400 including an example impedance matching interconnect consistent with one embodiment of the present disclosure. Example system 400 includes an interconnect system that includes first region 402, a second region 404 and an interface region 406 that includes an impedance matching interconnect consistent with the present disclosure. Example system 400 further includes a fourth region 410 that is coupled to the interconnect system at an end of the second region 404. System 400 may correspond to a cable, a PCB or an integrated circuit package substrate.

The first region 402 has width W1 and length L1 and corresponds to, for example, the first regions 102 and/or 202 of FIGS. 1, 2 and 3. Width W1 is related to first trace width, trace separation and number of first traces included in example system 400. For example, trace separation may be a minimum, as described herein. The second region 404 has width W2 and length L4 and corresponds to, for example, the second regions 104 and/or 204 of FIGS. 1, 2, and 3. Width W2 may be related to second trace width, trace separation and number of second traces included in example system 400. The number of second traces corresponds to the number of first traces. The interface region 406 includes two subregions 406a and 406b having a respective length L2 and L3. Lengths L2 and L3 may be related to an area available for the first region 402 and impedance matching interconnect 406. For example, L2 may be relatively larger when the available area is relatively more constrained. Subregion 406a corresponds to a portion of the impedance matching interconnect adjacent the first region 402. For example, an interface trace width of interface traces included in subregion 406a may be constant. In another example, the interface trace width may begin to increase in subregion 406a, as described herein. The width of the interface region 406 corresponds to W1 at a first end 403 and corresponds to W2 at a second end 405. The interface region 406 and/or interface subregion 406b corresponds to, for example, the impedance matching interconnects 106, 206 and/or 306 of FIGS. 1, 2, and 3, respectively.

Fourth region 410 is coupled to the second region 404 at second end of the second region 404. The impedance matching interconnect 406 is coupled to the second region at a first end of the second region 404. Area constraints for the fourth region 410 may be less than corresponding constraints for the second region 404. For example, trace widths in the fourth region may be greater than the corresponding trace widths in the second region. Impedance mismatch between the second region 404 and the fourth region 410 may be minimized by a corresponding increase in trace separation. In another example, trace widths in the fourth region may correspond to trace widths in the second region. In this second example, trace separation in the fourth region 410 may then correspond to trace separation in the second region 404.

The regions 402, 404, 406, 410 may each include one or more respective traces. For example, the regions 402, 404, 406, 410 may include two traces configured to support differential signals. In another example, the regions 402, 404, 406, 410 may include more than two traces. Width W1 is in the range 10 millimeters (mm) to 12 mm and width W2 is in the range 30 mm to 32 mm. For example, the width W1 may be 10.5 mm and width W2 may be 30 mm. In this example, the regions 402, 404, 406, 410 may each include 32 traces.

Continuing with this example 400, L1 may be 10 mm, L2 may be 3 mm, L3 may be 7 mm, L4 may be 3 mm and L5 may be 7 mm for a total length of 30 mm. Example 400 is one nonlimiting example of a transmission line that includes an impedance matching interconnect, as described herein. In other examples, values of L1, L2, L3, L4 and/or L5 may be greater than or less than the values shown for example 400. Value(s) of L1, L2, L3, L4 and/or L5 may be related to number of traces and/or available area in an application for at least the first region of an interconnect system, e.g., first region 402 of interconnect system portion 400.

FIGS. 4B and 4C may be best understood when considered together and in consideration of FIG. 4A. FIG. 4B illustrates a stack-up 420 of the first end 403 of the example interconnect 406 of FIG. 4A. FIG. 4C illustrates a stack-up 440 of the second end of the example interconnect 406 of FIG. 4A. Stack-up 420 corresponds to a sectional view in a direction A-A′ of the first end 402 of the example interconnect 406. Stack-up 440 corresponds to a sectional view in a direction B-B′ of the second end 405 of the example interconnect 406.

Stack-up 420 includes a plurality (e.g., two) of first traces 410a, 410b. Each first trace 410a, 410b has trace width TW₁ and first traces 410a, 410b are separated by trace separation TS. Stack-up 420 further includes a first dielectric layer 412, a first reference plane 414, a first subplane dielectric layer 416 and a second subplane layer 425. Stack-up 440 includes the plurality (e.g., two) of second traces 420a, 420b. Each second trace 420a, 420b has trace width TW₂ and second traces 420a, 420b are separated by trace separation TS₂. Stack-up 440 further includes a second dielectric layer 422 and a second reference plane 424. Stack-up 420 and stack-up 440 may further include a first overlay 411 and/or a second overlay 413. For example, overlays 411, 413 may include dielectric material, as described herein. Second subplane layer 425 may correspond to the second reference plane or may be etched away and filled with dielectric so that first subplane dielectric layer 416 and second subplane layer 425 together form a subplane dielectric layer, e.g., layer 116 of FIG. 1.

First dielectric layer 412 has thickness D1ₜ, first reference plane 414 has thickness R1ₜ, first subplane dielectric layer 416 has thickness DSₜ and second subplane layer 425 has thickness R2ₜ. Thickness DS1ₜ may correspond to via height Vₕ of FIG. 1. DS1ₜ plus R2ₜ may correspond to subplane 116 thickness DSₜ of FIG. 1. Second dielectric layer 422 has thickness D2ₜ and second reference plane 424 has thickness R2ₜ. Thus, D2ₜ is related to a sum of D1ₜ and DS1ₜ. For example, D2ₜ may be approximately equal to D1ₜ plus DS1ₜ, assuming a relatively small first reference plane thickness R1ₜ. For example, for a first dielectric region thickness D1ₜ of one mil (thousandth of an inch) and a first subplane region thickness DS1ₜ of two mil, the second dielectric thickness D2ₜ is approximately three mil.

Thus, an impedance matching interconnect, e.g., impedance matching interconnect 406, may be configured to reduce and/or minimize impedance mismatch between a first region and a second region. The first region may include relatively narrow traces with relatively narrow spacing and a relatively thin dielectric thickness. The second region may include relatively wide traces with relatively wider spacing and a relatively thick dielectric thickness. The impedance matching interconnect is configured to reduce and/or minimize impedance mismatch between the two regions and, thus supports a relatively thicker dielectric in the second region.

FIG. 5 is a plot 500 of differential impedance for an interconnect system consistent with one embodiment of the present disclosure. Plot 500 illustrates simulated differential impedance versus time related to differential signals applied to adjacent traces. Plot 500 includes a first region 502 and a second region 504. The first region 502 corresponds to narrow trace widths with relatively narrow trace separation and relatively thin dielectric, e.g., breakout region, and the second region 504 corresponds to relatively wide trace widths, relatively wider trace separation and relatively thick dielectric.

Plot 500 includes waveform 506 that corresponds to a simulated differential impedance for an example system that includes an example interconnect system consistent with one embodiment of the present disclosure. The example system was configured according to example system 400 of FIG. 4A with first region stack-up and second region stack-up as shown in FIGS. 4B and 4C. The example interconnect system was configured with first trace width TW₁ of 60 μm, first trace separation TS₁ of 60 μm, first dielectric region thickness D1ₜ of 1 mil, second trace width TW₂ of 118 μm, second trace separation TS₂ of 60 μm and second dielectric region thickness D2ₜ of 3 mil. Continuing with this example, the widths of the interface traces were uniform at 60 μm in region 402 and subregion 406a and transitioned linearly from 60 μm to 118 μm in subregion 406b. The widths of second traces were constant at 118 μm in second region 404. Trace separation was uniform at 60 μm in regions 402, 404 and 406. Trace width was 190 μm and trace separation was 450 μm for traces in the fourth region 410. In this example, impedance matching between the second region 404 and the fourth region 410 was supported by increasing the trace separation with trace width in the fourth region 410.

Generally, interconnect systems used for coupling electronic components may be configured to meet a specified differential impedance, e.g., 85 ohms±10%. It may be appreciated that the example interconnect system associated with plot 500 appears to meet such specification.

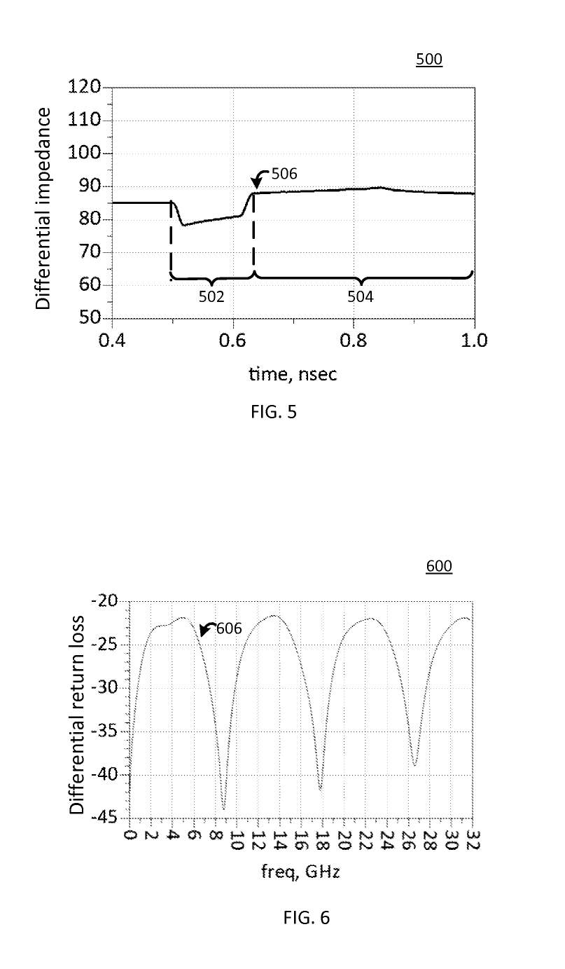

FIG. 6 is a plot 600 of differential return loss 606 for the example system characterized in FIG. 5. The simulated differential return loss is generally less than −20 dB (decibels).

Thus, consistent with the teachings of the present disclosure, an interconnect system may include a first region, a second region and an impedance matching interconnect configured to couple the first region and the second region. The impedance matching interconnect is configured to reduce and/or minimize impedance mismatch between the first region and the second region. The first region includes a relatively narrow first trace, relatively thin first dielectric layer and a first reference plane and has an associated first characteristic impedance. The second region includes a relatively wide second trace, relatively thick second dielectric layer and a second reference plane. The thickness of the second dielectric layer may be selected so that a second characteristic impedance of the second region corresponds to the first characteristic impedance of the first region. In other words, thickness of the second dielectric layer may be selected to reduce and/or minimize impedance mismatch between the first region and the second region.

The impedance matching interconnect includes an interface trace, the first dielectric layer, the first reference plane, the second reference plane and a via coupling the first reference plane and the second reference plane. The impedance matching interconnect has a first end and a second end. The interface trace has a first width at the first end and a second width at the second end of the impedance matching interconnect. The first width is configured to correspond to a width of the relatively narrow first trace and the second width is configured to correspond to a width of the relatively wide second trace. A sum of the thickness of the first dielectric layer, a thickness of the first reference plane and a height of the via is configured to correspond to the thickness of the second dielectric layer.

“Circuitry”, as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry. The logic may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc.

Thus, tight space constraints may be accommodated by the first region, reduced transmission losses may be provided in the second region and impedance mismatch may be reduced and/or minimized by the impedance matching interconnect. The interconnect system may remain generally flexible since the first region and the second region may be considered a two metal layer design, i.e., each of the first and second regions includes two conductive (e.g., metal) layers separated by a dielectric material.

### Examples

Examples of the present disclosure include subject material such as a method, means for performing acts of the method, a device, or of an apparatus or system related to an impedance matching interconnect, as discussed below.

### Example 1

According to this example there is provided an apparatus. The apparatus includes an impedance matching interconnect having a first end and a second end. The impedance matching interconnect includes an interface trace having a first width at the first end and a second width at the second end, the first width less than the second width. The impedance matching interconnect includes a first dielectric layer adjacent the interface trace; a first reference plane adjacent the first dielectric layer; at least one via adjacent the first reference plane; and a second reference plane adjacent the at least one via, the at least one via to couple the first reference plane and the second reference plane, a first distance between the interface trace and the first reference plane less than a second distance between the interface trace and the second reference plane.

### Example 2

This example includes the elements of example 1, wherein the first reference plane ends at the second end or between the first end and the second end of the impedance matching interconnect.

### Example 3

This example includes the elements of example 1, wherein an end of the second reference plane corresponds to the first end of the impedance matching interconnect.

### Example 4

This example includes the elements according to any one of examples 1 through 3, wherein the impedance matching interconnect is rigid.

### Example 5

This example includes the elements according to any one of examples 1 through 3, wherein the impedance matching interconnect is semi-rigid or flexible.

### Example 6

This example includes the elements according to any one of examples 1 through 3, wherein the first distance is one mil (thousandth of an inch) plus or minus a tolerance and the second distance is three mil plus or minus the tolerance.

### Example 7

This example includes the elements according to any one of examples 1 through 3, wherein the impedance matching interconnect is to reduce an impedance mismatch between a first region and a second region.

### Example 8

This example includes the elements according to any one of examples 1 through 3, wherein the interface trace is the first width at a location between the first end and the second end.

### Example 9

This example includes the elements according to any one of examples 1 through 3, wherein the impedance matching interconnect includes a plurality of interface traces.

### Example 10

This example includes the elements according to any one of examples 1 through 3, wherein the first width is in the range 50 micrometers (□m) to 60 □m and the second width is in the range 100 □m to 200 □m.

### Example 11

This example includes the elements according to any one of examples 1 through 3, wherein the second distance is related to a dielectric thickness of a second region, the second region dielectric thickness selected so that a characteristic impedance of the second region corresponds to a characteristic impedance of a first region.

### Example 12

This example includes the elements according to any one of examples 1 through 3, wherein the second distance corresponds to a sum of the first distance, a thickness of the first reference plane and a height of the at least one via.

### Example 13

This example includes the elements according to any one of examples 1 through 3, wherein a height of the at least one via corresponds to a distance between the first reference plane and the second reference plane.

### Example 14

This example includes the elements of example 13, wherein the via height is 2 mil (thousandths of an inch).

### Example 15

This example includes the elements of example 13, wherein the via height is 4 mil (thousandths of an inch).

### Example 16

This example includes the elements according to any one of examples 1 through 3, wherein a width of the interface trace increases uniformly from the first end to the second end.

### Example 17

This example includes the elements according to any one of examples 1 through 3, wherein a width of the interface trace decreases uniformly from the second end to a location between the first end and the second end, the width of the interface trace corresponding to the first width between the location and the first end.

### Example 18

This example includes the elements according to any one of examples 1 through 3, wherein a shape of an end of the first reference plane is uniform.

### Example 19

This example includes the elements according to any one of examples 1 through 3, wherein a shape of an end of the first reference plane is nonuniform.

### Example 20

This example includes the elements according to any one of examples 1 through 3, wherein a rate of change of a trace separation in the impedance matching interconnect is related to mitigating impedance mismatch between a first region and a second region.

### Example 21

This example includes the elements according to any one of examples 1 through 3, wherein a rate of change of a width of the interface trace is related to mitigating impedance mismatch between a first region and a second region.

### Example 22

This example includes the elements according to any one of examples 1 through 3, wherein an end of the first reference plane corresponds to the second end of the impedance matching interconnect.

### Example 23

This example includes the elements according to any one of examples 1 through 3, wherein the first dielectric layer includes a dielectric material selected from the group including liquid crystal polymer (LCP), glass fiber epoxy laminate, polyimide film and glass microfiber reinforced PTFE (polytetrafluoroethylene).

### Example 24

According to this example there is provided a method. The method includes coupling, by an impedance matching interconnect, a first region and a second region. The first region includes a first trace, a first dielectric layer adjacent the first trace, and a first reference plane adjacent the first dielectric layer. The second region includes a second trace, a second dielectric layer adjacent the second trace, and a second reference plane. The impedance matching interconnect includes an interface trace having a first width at a first end of the impedance matching interconnect and a second width at a second end of the impedance matching interconnect, the first width less than the second width. The impedance matching interconnect further includes the first dielectric layer, the first reference plane, at least one via adjacent the first reference plane, and the second reference plane adjacent the at least one via, the at least one via to couple the first reference plane and the second reference plane. A first distance between the interface trace and the first reference plane is less than a second distance between the interface trace and the second reference plane.

### Example 25

This example includes the elements of example 24, wherein the first reference plane ends at the second end or between the first end and the second end of the impedance matching interconnect.

### Example 26

This example includes the elements of example 24, wherein an end of the second reference plane corresponds to the first end of the impedance matching interconnect.

### Example 27

This example includes the elements of example 24, wherein the impedance matching interconnect is semi-rigid or flexible.

### Example 28

This example includes the elements of example 24, wherein the impedance matching interconnect is to reduce an impedance mismatch between the first region and the second region.

### Example 29

This example includes the elements of example 24, wherein the impedance matching interconnect includes a plurality of vias to couple the first reference plane and the second reference plane.

### Example 30

This example includes the elements of example 29, wherein the plurality of vias is arranged in a line.

### Example 31

This example includes the elements of example 29, wherein the plurality of vias is staggered.

### Example 32

This example includes the elements of example 24, wherein the first region includes a plurality of first traces and the second region includes a plurality of second traces.

### Example 33

This example includes the elements of example 32, wherein a trace separation between an adjacent two of the plurality of first traces is greater than or equal to 60 micrometers (□m) and a trace separation between an adjacent two of the plurality of second traces is greater than or equal to 60 □m.

### Example 34

This example includes the elements of example 24, wherein the interface trace is the first width at a location between the first end and the second end.

### Example 35

This example includes the elements of example 24, wherein the first width is in the range 50 micrometers (□m) to 60 □m and the second width is in the range 100 □m to 200 □m.

### Example 36

This example includes the elements of example 24, wherein the second distance is related to a dielectric thickness of the second region, the second region dielectric thickness selected so that a characteristic impedance of the second region corresponds to a characteristic impedance of the first region.

### Example 37

This example includes the elements of example 24, wherein the first width corresponds to a width of the first trace and the second width corresponds to a width of the second trace.

### Example 38

This example includes the elements of example 24, wherein the second distance corresponds to a sum of the first distance, a thickness of the first reference plane and a height of the via.

### Example 39

This example includes the elements of example 24, wherein the first region is flexible and/or semi-rigid.

### Example 40

This example includes the elements of example 24, wherein the first region is rigid.

### Example 41

This example includes the elements of example 24, wherein the second region is flexible and/or semi-rigid.

### Example 42

This example includes the elements of example 24, wherein the second region is rigid.

### Example 43

This example includes the elements of example 24, wherein the first region is configured for use in a location with limited space available.

### Example 44

This example includes the elements of example 24, wherein the first region corresponds to a breakout region.

### Example 45

This example includes the elements of example 44, wherein the second region corresponds to a mainroute region.

### Example 46

This example includes the elements of example 24, wherein the first region and second region each includes two conductive layers.

### Example 47

This example includes the elements of example 24, wherein a height of the via corresponds to a distance between the first reference plane and the second reference plane.

### Example 48

This example includes the elements of example 47, wherein the via height is 2 mil (thousandths of an inch).

### Example 49

This example includes the elements of example 47, wherein the via height is 4 mil (thousandths of an inch).

### Example 50

This example includes the elements of example 24, wherein a width of the interface trace increases uniformly from the first end to the second end.

### Example 51

This example includes the elements of example 24, wherein a width of the interface trace decreases uniformly from the second end to a location between the first end and the second end, the width of the interface trace corresponding to the first width between the location and the first end.

### Example 52

This example includes the elements of example 24, wherein a shape of an end of the first reference plane is uniform.

### Example 53

This example includes the elements of example 24, wherein a shape of an end of the first reference plane is nonuniform.

### Example 54

This example includes the elements of example 24, wherein a rate of change of a trace separation in the impedance matching interconnect is related to mitigating impedance mismatch between a first region and a second region.

### Example 55

This example includes the elements of example 24, wherein a rate of change of a width of the interface trace is related to mitigating impedance mismatch between the first region and the second region.

### Example 56

This example includes the elements of example 24, wherein the impedance matching interconnect is rigid.

### Example 57

This example includes the elements of example 24, wherein an end of the first reference plane corresponds to the second end of the impedance matching interconnect.

### Example 58

According to this example there is provided an interconnect system. The interconnect system includes a first region, a second region and an impedance matching interconnect. The first region includes a first trace, a first dielectric layer adjacent the first trace, and a first reference plane adjacent the first dielectric layer. The second region includes a second trace, a second dielectric layer adjacent the second trace, and a second reference plane. The impedance matching interconnect is coupled to the first region at a first end of the interconnect and the second region at a second end of the interconnect. The impedance matching interconnect includes an interface trace having a first width at the first end and a second width at the second end, the first width less than the second width. The impedance matching interconnect further includes the first dielectric layer, the first reference plane, at least one via adjacent the first reference plane, and the second reference plane adjacent the at least one via. The at least one via is to couple the first reference plane and the second reference plane. A first distance between the interface trace and the first reference plane is less than a second distance between the interface trace and the second reference plane.

### Example 59

This example includes the elements of example 58, wherein the first reference plane ends at the second end or between the first end and the second end of the impedance matching interconnect.

### Example 60

This example includes the elements of example 58, wherein an end of the second reference plane corresponds to the first end of the impedance matching interconnect.

### Example 61

This example includes the elements according to any one of examples 58 through 60, wherein the impedance matching interconnect is rigid.

### Example 62

This example includes the elements according to any one of examples 58 through 60, wherein the impedance matching interconnect is semi-rigid or flexible.

### Example 63

This example includes the elements according to any one of examples 58 through 60, wherein the first distance is one mil (thousandth of an inch) plus or minus a tolerance and the second distance is three mil plus or minus the tolerance.

### Example 64

This example includes the elements according to any one of examples 58 through 60, wherein the impedance matching interconnect is to reduce an impedance mismatch between the first region and the second region.

### Example 65

This example includes the elements according to any one of examples 58 through 60, wherein the impedance matching interconnect includes a plurality of vias to couple the first reference plane and the second reference plane.

### Example 66

This example includes the elements of example 65, wherein the plurality of vias is arranged in a line.

### Example 67

This example includes the elements of example 65, wherein the plurality of vias is staggered.

### Example 68

This example includes the elements according to any one of examples 58 through 60, wherein the first region includes a plurality of first traces and the second region includes a plurality of second traces.

### Example 69

This example includes the elements of example 68, wherein a trace separation between an adjacent two of the plurality of first traces is greater than or equal to 60 micrometers (□m) and a trace separation between an adjacent two of the plurality of second traces is greater than or equal to 60 □m.

### Example 70

This example includes the elements according to any one of examples 58 through 60, wherein the interface trace is the first width at a location between the first end and the second end.

### Example 71

This example includes the elements according to any one of examples 58 through 60, wherein the first width is in the range 50 micrometers (□m) to 60 □m and the second width is in the range 100 □m to 200 □m.

### Example 72

This example includes the elements according to any one of examples 58 through 60, wherein the second distance is related to a dielectric thickness of the second region, the second region dielectric thickness selected so that a characteristic impedance of the second region corresponds to a characteristic impedance of the first region.

### Example 73

This example includes the elements according to any one of examples 58 through 60, wherein the first width corresponds to a width of the first trace and the second width corresponds to a width of the second trace.

### Example 74

This example includes the elements according to any one of examples 58 through 60, wherein the second distance corresponds to a sum of the first distance, a thickness of the first reference plane and a height of the via.

### Example 75

This example includes the elements according to any one of examples 58 through 60, wherein the first region is flexible and/or semi-rigid.

### Example 76

This example includes the elements according to any one of examples 58 through 60, wherein the first region is rigid.

### Example 77

This example includes the elements according to any one of examples 58 through 60, wherein the second region is flexible and/or semi-rigid.

### Example 78

This example includes the elements according to any one of examples 58 through 60, wherein the second region is rigid.

### Example 79

This example includes the elements according to any one of examples 58 through 60, wherein the first region is configured for use in a location with limited space available.

### Example 80

This example includes the elements according to any one of examples 58 through 60, wherein the first region corresponds to a breakout region.

### Example 81

This example includes the elements of example 80, wherein the second region corresponds to a mainroute region.

### Example 82

This example includes the elements according to any one of examples 58 through 60, wherein the first region and second region each includes two conductive layers.

### Example 83

This example includes the elements according to any one of examples 58 through 60, wherein a height of the at least one via corresponds to a distance between the first reference plane and the second reference plane.

### Example 84

This example includes the elements of example 83, wherein the via height is 2 mil (thousandths of an inch).

### Example 85

This example includes the elements of example 83, wherein the via height is 4 mil (thousandths of an inch).

### Example 86

This example includes the elements according to any one of examples 58 through 60, wherein a width of the interface trace increases uniformly from the first end to the second end.

### Example 87

This example includes the elements according to any one of examples 58 through 60, wherein a width of the interface trace decreases uniformly from the second end to a location between the first end and the second end, the width of the interface trace corresponding to the first width between the location and the first end.

### Example 88

This example includes the elements according to any one of examples 58 through 60, wherein a shape of an end of the first reference plane is uniform.

### Example 89

This example includes the elements according to any one of examples 58 through 60, wherein a shape of an end of the first reference plane is nonuniform.

### Example 90

This example includes the elements according to any one of examples 58 through 60, wherein a rate of change of a trace separation in the impedance matching interconnect is related to mitigating impedance mismatch between the first region and the second region.

### Example 91

This example includes the elements according to any one of examples 58 through 60, wherein a rate of change of a width of the interface trace is related to mitigating impedance mismatch between the first region and the second region.

### Example 92

This example includes the elements according to any one of examples 58 through 60, wherein an end of the first reference plane corresponds to the second end of the impedance matching interconnect.

### Example 93

This example includes the elements according to any one of examples 58 through 60, wherein the first dielectric layer and the second dielectric layer each includes a dielectric material selected from the group including liquid crystal polymer (LCP), glass fiber epoxy laminate, polyimide film and glass microfiber reinforced PTFE (polytetrafluoroethylene).

### Example 94

According to this example there is provided a system. The system includes an interconnect system. The interconnect system includes a first region, a second region and an impedance matching interconnect. The first region includes a first trace, a first dielectric layer adjacent the first trace, and a first reference plane adjacent the first dielectric layer. The second region includes a second trace, a second dielectric layer adjacent the second trace, and a second reference plane. The impedance matching interconnect is coupled to the first region at a first end of the interconnect and the second region at a second end of the interconnect. The impedance matching interconnect includes an interface trace having a first width at the first end and a second width at the second end, the first width less than the second width. The impedance matching interconnect further includes the first dielectric layer, the first reference plane, at least one via adjacent the first reference plane, and the second reference plane adjacent the at least one via. The at least one via is to couple the first reference plane and the second reference plane. A first distance between the interface trace and the first reference plane is less than a second distance between the interface trace and the second reference plane.

### Example 95

This example includes the elements of example 94, wherein the first reference plane ends at the second end or between the first end and the second end of the impedance matching interconnect.

### Example 96

This example includes the elements of example 94, wherein an end of the second reference plane corresponds to the first end of the impedance matching interconnect.

### Example 97

This example includes the elements of example 94, wherein the impedance matching interconnect is to reduce an impedance mismatch between the first region and the second region.

### Example 98

This example includes the elements according to any one of examples 94 through 97, wherein the system is a flexible cable.

### Example 99

This example includes the elements according to any one of examples 94 through 97, wherein the system is a printed circuit board.

### Example 100

This example includes the elements according to any one of examples 94 through 97, wherein the system is an integrated circuit package substrate.

### Example 101

This example includes the elements according to any one of examples 94 through 97, wherein the interconnect system corresponds to at least a portion of a flexible cable.

### Example 102

This example includes the elements according to any one of examples 94 through 97, wherein the interconnect system corresponds to at least a portion of a printed circuit board.

### Example 103

This example includes the elements according to any one of examples 94 through 97, wherein the interconnect system corresponds to at least a portion of an integrated circuit package.

### Example 104

A system including at least one device arranged to perform the method of any one of claims 24 to 57.

### Example 105

A device including means to perform the method of any one of claims 24 to 57.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. An apparatus comprising:
an impedance matching interconnect having a first end and a second end, the impedance matching interconnect comprising:
an interface trace having a first width at the first end and a second width at the second end, the first width less than the second width;
a first dielectric layer adjacent the interface trace;
a first reference plane adjacent the first dielectric layer;
at least one via adjacent the first reference plane; and
a second reference plane adjacent the at least one via, the at least one via to couple the first reference plane and the second reference plane,
a first distance between the interface trace and the first reference plane less than a second distance between the interface trace and the second reference plane.

2. The apparatus of claim 1, wherein the first reference plane ends at the second end or between the first end and the second end of the impedance matching interconnect.

3. The apparatus of claim 1, wherein an end of the second reference plane corresponds to the first end of the impedance matching interconnect.

4. The apparatus of claim 1, wherein the impedance matching interconnect is semi-rigid or flexible.

5. The apparatus of claim 1, wherein the impedance matching interconnect is to reduce an impedance mismatch between a first region and a second region.

6. The apparatus of claim 1, wherein the second distance corresponds to a sum of the first distance, a thickness of the first reference plane and a height of the at least one via.

7. The apparatus of claim 1, wherein a shape of an end of the first reference plane is uniform.

8. The apparatus of claim 1, wherein a shape of an end of the first reference plane is nonuniform.

9. The apparatus of claim 1, wherein a rate of change of a trace separation in the impedance matching interconnect is related to mitigating impedance mismatch between a first region and a second region.

10. The apparatus of claim 1, wherein a rate of change of a width of the interface trace is related to mitigating impedance mismatch between a first region and a second region.

11. The apparatus of claim 1, wherein the impedance matching interconnect is rigid.

12. The apparatus of claim 1, wherein the second distance is related to a dielectric thickness of a second region, the second region dielectric thickness selected so that a characteristic impedance of the second region corresponds to a characteristic impedance of a first region.

13. An interconnect system comprising:
a first region comprising a first trace, a first dielectric layer adjacent the first trace, and a first reference plane adjacent the first dielectric layer;
a second region comprising a second trace, a second dielectric layer adjacent the second trace, and a second reference plane; and
an impedance matching interconnect coupled to the first region at a first end of the interconnect and the second region at a second end of the interconnect, the impedance matching interconnect comprising an interface trace having a first width at the first end and a second width at the second end, the first width less than the second width, the impedance matching interconnect further comprising the first dielectric layer, the first reference plane, at least one via adjacent the first reference plane, and the second reference plane adjacent the at least one via, the at least one via to couple the first reference plane and the second reference plane,
a first distance between the interface trace and the first reference plane less than a second distance between the interface trace and the second reference plane.

14. The interconnect system of claim 13, wherein the first reference plane ends at the second end or between the first end and the second end of the impedance matching interconnect.

15. The interconnect system of claim 13, wherein an end of the second reference plane corresponds to the first end of the impedance matching interconnect.

16. The interconnect system of claim 13, wherein the impedance matching interconnect is semi-rigid or flexible.

17. The interconnect system of claim 13, wherein the impedance matching interconnect is to reduce an impedance mismatch between the first region and the second region.

18. The interconnect system of claim 13, wherein the second distance corresponds to a sum of the first distance, a thickness of the first reference plane and a height of the at least one via.

19. The interconnect system of claim 13, wherein a shape of an end of the first reference plane is uniform.

20. The interconnect system of claim 13, wherein a shape of an end of the first reference plane is nonuniform.

21. The interconnect system of claim 13, wherein a rate of change of a trace separation in the impedance matching interconnect is related to mitigating impedance mismatch between the first region and the second region.

22. The interconnect system of claim 13, wherein a rate of change of a width of the interface trace is related to mitigating impedance mismatch between the first region and the second region.

23. The interconnect system of claim 13, wherein the impedance matching interconnect is rigid.

24. The interconnect system of claim 13, wherein the second distance is related to a dielectric thickness of the second region, the second region dielectric thickness selected so that a characteristic impedance of the second region corresponds to a characteristic impedance of the first region.

25. The interconnect system of claim 13, wherein the first region and second region each includes two conductive layers.
